(19) United States
(12) Patent Application Publication
(10) Pub. No.: US 2020/0396840 A1
(43) Pub. Date: Dec. 17, 2020

(54) IN-MOLD ELECTRONICS AND THEIR METHODS OF MANUFACTURE

(71) Applicant: SRG GLOBAL LIRIA, S.L., LIRIA (ES)

(72) Inventor: JAVIER RODRIGO GRANDIA, VALENCIA (ES)

(73) Assignee: SRG GLOBAL LIRIA, S.L., LIRIA (ES)

(21) Appl. No.: 16/946,331

(22) Filed: Jun. 17, 2020

(30) Foreign Application Priority Data
Jun. 17, 2019 (ES) P201930553

(51) Int. Cl. H05K 3/00; H05K 1/02

(52) U.S. Cl. CPC H05K 3/0014; H05K 5/0243; H05K 2203/13; H05K 1/0293

(57) ABSTRACT

In-mold electronic (IME) devices and their methods of manufacture comprise providing a substrate, a conductive track disposed on or proximate to a first surface of the substrate, a light-emitting diode (LED) disposed on the first surface of the substrate, electrically connected to the conductive track, and configured to emit light, a light channel layer applied to the substrate, the light channel layer comprising a transparent or translucent portion covering or surrounding the LED, and a decorative layer applied to the light channel layer or an opposing second surface of the substrate, the decorative layer defining an opaque portion and a transparent or translucent portion through which light emitted by the LED flows.

### CROSS-REFERENCE TO RELATED APPLICATION(S)

The present application claims the benefit of Spanish Patent Application No. P201930553 filed Jun. 17, 2019. The disclosure of the above-identified application is incorporated herein by reference in its entirety.

### FIELD

The present application relates to in-mold electronics and their methods of manufacture.

### BACKGROUND

An in-mold electronic (IME) device combines in-mold decorative technology with printed electronics. These printed electronics can include, but are not limited to, capacitive, resistive, and piezoelectric sensing technologies, lighting features, and combinations thereof. One benefit of IME devices is the ability to integrate traditional human-machine interface (HMI) features (e.g., switches) into aesthetically pleasing components. Non-limiting example applications of IME devices include vehicle interior and exterior components, appliances, and consumer goods.

### SUMMARY

According to one aspect of the present disclosure, an in-mold electronic (IME) device is presented. In one exemplary implementation, the IME device comprises: a substrate, a conductive track disposed on or proximate to a first surface of the substrate, a light-emitting diode (LED) disposed on the first surface of the substrate, electrically connected to the conductive track, and configured to emit light, a light channel layer applied to the substrate, the light channel layer comprising a transparent or translucent portion covering and/or surrounding the LED, and a decorative layer applied to the light channel layer or an opposing second surface of the substrate, the decorative layer defining an opaque portion and a transparent or translucent portion through which light emitted by the LED flows.

In some implementations, the substrate is transparent or translucent and the decorative layer is disposed on the opposing second surface of the substrate. In some implementations, the light channel layer further comprises an opaque portion surrounding its transparent or translucent portion.

In some implementations, the light channel layer further comprises an opaque portion surrounding the transparent or translucent portion. In some implementations, wherein the decorative layer is disposed on the opaque portion of the light channel layer. In some implementations, the decorative layer comprises a transparent or translucent decorative film disposed on the opaque portion of the light channel layer and an outer decorative layer disposed on the decorative film, the outer decorative layer defining an opaque portion and the transparent or translucent portion. In some implementations, the conductive track is disposed on an inner surface of the transparent or translucent decorative film.

According to another aspect of the present disclosure, an IME device is presented. In one exemplary implementation, the IME device comprises: a substrate, a conductive track disposed on or proximate to a first surface of the substrate, an LED disposed on the first surface of the substrate, electrically connected to the conductive track, and configured to emit light, a light channel layer applied to the substrate, the light channel layer comprising a transparent or translucent portion proximate to and about the LED, and a decorative layer applied to the light channel layer or an opposing second surface of the substrate, the decorative layer defining an opaque portion and a transparent or translucent portion through which light emitted by the LED flows.

In some implementations, the transparent or translucent portion of the light channel layer does not contact the LED, wherein the substrate is transparent or translucent, wherein the decorative layer is disposed on the opposing second surface of the substrate, and wherein the transparent or translucent portion of the decorative layer is aligned with the light channel layer.

In some implementations, the transparent or translucent portion of the light channel layer surrounds or covers the LED, wherein the substrate is transparent or translucent, wherein the decorative layer is disposed on the opposing second surface of the substrate, and wherein the light channel layer further comprises an opaque portion surrounding its transparent or translucent portion. In some implementations, the transparent or translucent portion of the decorative layer is aligned with the light channel layer to provide a direct illumination effect. In some implementations, the transparent or translucent portion of the decorative layer is not aligned with the light channel layer to provide an indirect illumination effect.

In some implementations, the transparent or translucent portion of the light channel layer surrounds or covers the LED, wherein the light channel layer further comprises an opaque portion thereabout its transparent or translucent portion, and wherein the decorative layer is disposed on the light channel layer. In some implementations, the decorative layer comprises a transparent or translucent decorative film disposed on the light channel layer and an outer decorative layer disposed on the decorative film, the outer decorative layer defining an opaque portion and the transparent or translucent portion. In some implementations, the transparent or translucent portion of the outer decorative layer is aligned with the transparent or translucent portion of the light channel layer to provide a direct illumination effect. In some implementations, the transparent or translucent portion of the outer decorative layer is not aligned with the light channel layer to provide an indirect illumination effect. In some implementations, the conductive track is disposed on an inner surface of the transparent or translucent decorative film.

According to another aspect of the present disclosure, an IME device is presented. In one exemplary implementation, the IME device comprises: a substrate, a conductive track disposed on or proximate to a first surface of the substrate, an LED disposed on the first surface of the substrate, electrically connected to the conductive track, and configured to emit light, a light channel layer applied to the substrate, the light channel layer comprising a transparent or translucent portion or an opaque portion proximate to and not in contact with the LED, and a decorative layer applied to the light channel layer or an opposing second surface of the substrate, the decorative layer defining an opaque portion and a transparent or translucent portion through which light emitted by the LED flows.

In some implementations, the light channel layer comprises the transparent or translucent portion proximate to and not in contact with the LED, wherein the substrate is transparent or translucent, wherein the decorative layer is disposed on the opposing second surface of the substrate, and wherein the LED is aligned with the transparent or translucent portion of the decorative layer.

In some implementations, the light channel layer comprises the opaque portion proximate to and not in contact with the LED and a transparent or translucent portion surrounding its opaque portion and the LED, wherein the substrate is transparent or translucent, wherein the decorative layer is disposed on the opposing second surface of the substrate, and wherein the LED is aligned with the transparent or translucent portion of the decorative layer.

In some implementations, the light channel layer comprises the opaque portion proximate to and not in contact with the LED and a transparent or translucent portion surrounding its opaque portion and the LED, wherein the substrate is transparent or translucent, wherein the decorative layer is disposed on the light channel layer, and wherein the LED is aligned with the transparent or translucent portion of the decorative layer. In some implementations, the decorative layer comprises a transparent or translucent decorative film disposed on the light channel layer and an outer decorative layer disposed on the decorative film, the outer decorative layer defining an opaque portion and the transparent or translucent portion. In some implementations, the conductive track is disposed on an inner surface of the transparent or translucent decorative film.

According to another aspect of the present disclosure, a method of manufacturing an IME device is presented. In one exemplary implementation, the method comprises: providing a substrate, applying a conductive track on or proximate to a first surface of the substrate, applying an LED to the first surface of the substrate and electrically connecting the LED to the conductive track, wherein the LED is configured to emit light, depositing a light channel layer on the substrate via a potting process, the light channel layer comprising a transparent or translucent portion surrounding or covering the LED, and applying a decorative layer applied to the light channel layer or an opposing second surface of the substrate, the decorative layer defining an opaque portion and a transparent or translucent portion through which light emitted by the LED flows.

In some implementations, the substrate is transparent or translucent and the decorative layer is disposed on the opposing second surface of the substrate. In some implementations, the light channel layer further comprises an opaque portion surrounding its transparent or translucent portion.

In some implementations, the light channel layer further comprises an opaque portion surrounding the transparent or translucent portion. In some implementations, the decorative layer is disposed on the opaque portion of the light channel layer. In some implementations, the decorative layer comprises a transparent or translucent decorative film disposed on the opaque portion of the light channel layer and an outer decorative layer disposed on the decorative film, the outer decorative layer defining an opaque portion and the transparent or translucent portion. In some implementations, the conductive track is applied to an inner surface of the transparent or translucent decorative film.

According to another aspect of the present disclosure, a method of manufacturing an IME device is presented. In one exemplary implementation, the method comprises: providing a substrate, applying a conductive track on or proximate to a first surface of the substrate, applying an LED to the first surface of the substrate and electrically connecting the LED to the conductive track, wherein the LED is configured to emit light, depositing a light channel layer on the substrate via a potting process, the light channel layer comprising a transparent or translucent portion proximate to and about the LED, and applying a decorative layer to the light channel layer or an opposing second surface of the substrate, the decorative layer defining an opaque portion and a transparent or translucent portion through which light emitted by the LED flows.

In some implementations, the transparent or translucent portion of the light channel layer does not contact the LED, wherein the substrate is transparent or translucent, wherein the decorative layer is disposed on the opposing second surface of the substrate, and wherein the transparent or translucent portion of the decorative layer is aligned with the light channel layer.

In some implementations, the transparent or translucent portion of the light channel layer surrounds or covers the LED, wherein the substrate is transparent or translucent, wherein the decorative layer is disposed on the opposing second surface of the substrate, and wherein the light channel layer further comprises an opaque portion surrounding its transparent or translucent portion. In some implementations, the transparent or translucent portion of the decorative layer is aligned with the light channel layer to provide a direct illumination effect. In some implementations, the transparent or translucent portion of the decorative layer is not aligned with the light channel layer to provide an indirect illumination effect.

In some implementations, the transparent or translucent portion of the light channel layer surrounds or covers the LED, wherein the light channel layer further comprises an opaque portion thereabout its transparent or translucent portion, and wherein the decorative layer is disposed on the light channel layer. In some implementations, the decorative layer comprises a transparent or translucent decorative film disposed on the light channel layer and an outer decorative layer disposed on the decorative film, the outer decorative layer defining an opaque portion and the transparent or translucent portion. In some implementations, the transparent or translucent portion of the outer decorative layer is aligned with the transparent or translucent portion of the light channel layer to provide a direct illumination effect. In some implementations, the transparent or translucent portion of the outer decorative layer is not aligned with the light channel layer to provide an indirect illumination effect. In some implementations, the conductive track is applied to an inner surface of the transparent or translucent decorative film.

According to another aspect of the present disclosure, a method of manufacturing an IME device is presented. In one exemplary implementation, the method comprises: providing a substrate, applying a conductive track on or proximate to a first surface of the substrate, applying an LED to the first surface of the substrate and electrically connecting the LED to the conductive track, wherein the LED is configured to emit light, depositing a light channel layer on the substrate via a potting process, the light channel layer comprising a transparent or translucent portion or an opaque portion proximate to and not in contact with the LED, and a decorative layer applied to the light channel layer or an opposing second surface of the substrate, the decorative layer defining an opaque portion and a transparent or translucent portion through which light emitted by the LED flows.

In some implementations, the light channel layer comprises the transparent or translucent portion proximate to and not in contact with the LED, wherein the substrate is transparent or translucent, wherein the decorative layer is disposed on the opposing second surface of the substrate, and wherein the LED is aligned with the transparent or translucent portion of the decorative layer.

In some implementations, the light channel layer comprises the opaque portion proximate to and not in contact with the LED and a transparent or translucent portion surrounding its opaque portion and the LED, wherein the substrate is transparent or translucent, wherein the decorative layer is disposed on the opposing second surface of the substrate, and wherein the LED is aligned with the transparent or translucent portion of the decorative layer.

In some implementations, the light channel layer comprises the opaque portion proximate to and not in contact with the LED and a transparent or translucent portion surrounding its opaque portion and the LED, wherein the substrate is transparent or translucent, wherein the decorative layer is disposed on the light channel layer, and wherein the LED is aligned with the transparent or translucent portion of the decorative layer. In some implementations, the decorative layer comprises a transparent or translucent decorative film disposed on the light channel layer and an outer decorative layer disposed on the decorative film, the outer decorative layer defining an opaque portion and the transparent or translucent portion. In some implementations, the conductive track is applied to an inner surface of the transparent or translucent decorative film.

Further areas of applicability of the teachings of the present disclosure will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the substance of the present disclosure are intended to be within the scope of the present disclosure.

### BRIEF DESCRIPTION OF THE DRAWINGS

FIGS. 1A-1D illustrate a side view and cross-sectional views of a first set of embodiments of an in-mold electronic (IME) device according to the principles of the present disclosure;

FIGS. 2A-2G illustrate a side view and cross-sectional views of a second set of embodiments of an IME device according to the principles of the present disclosure; and

FIGS. 3A-3F illustrate a side view and cross-sectional views of a third set of embodiments of an IME device according to the principles of the present disclosure.

### DETAILED DESCRIPTION

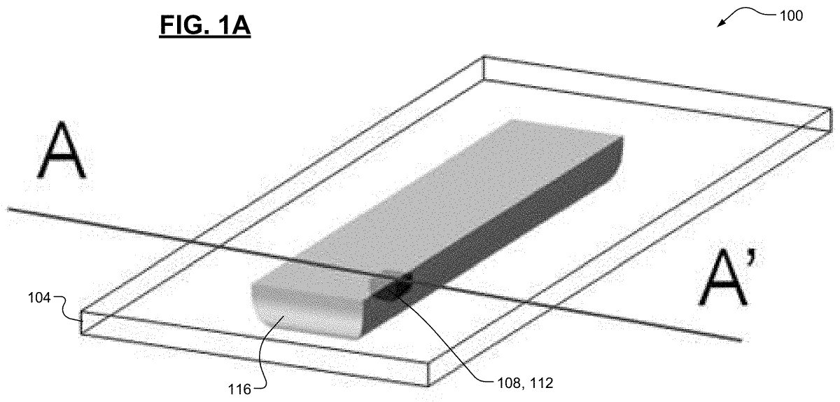

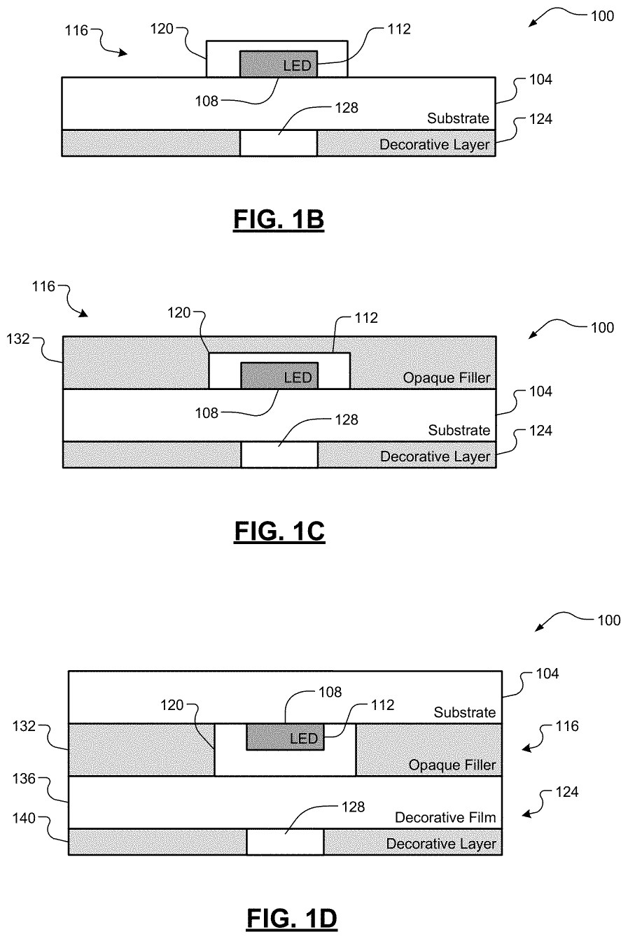

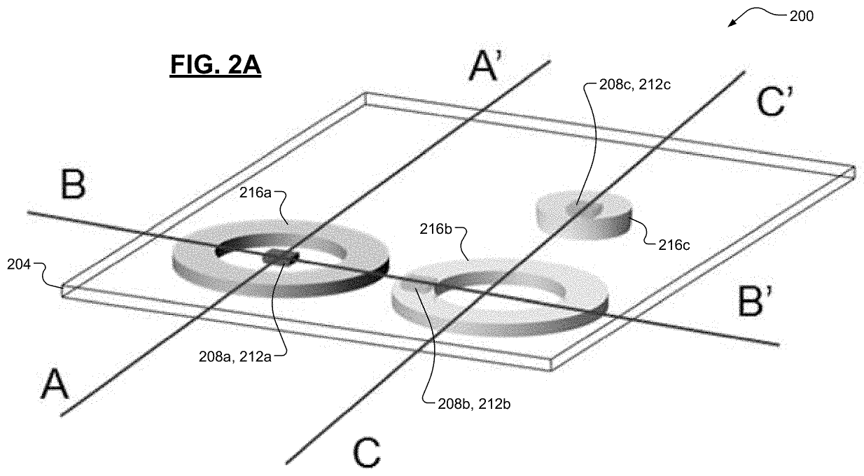

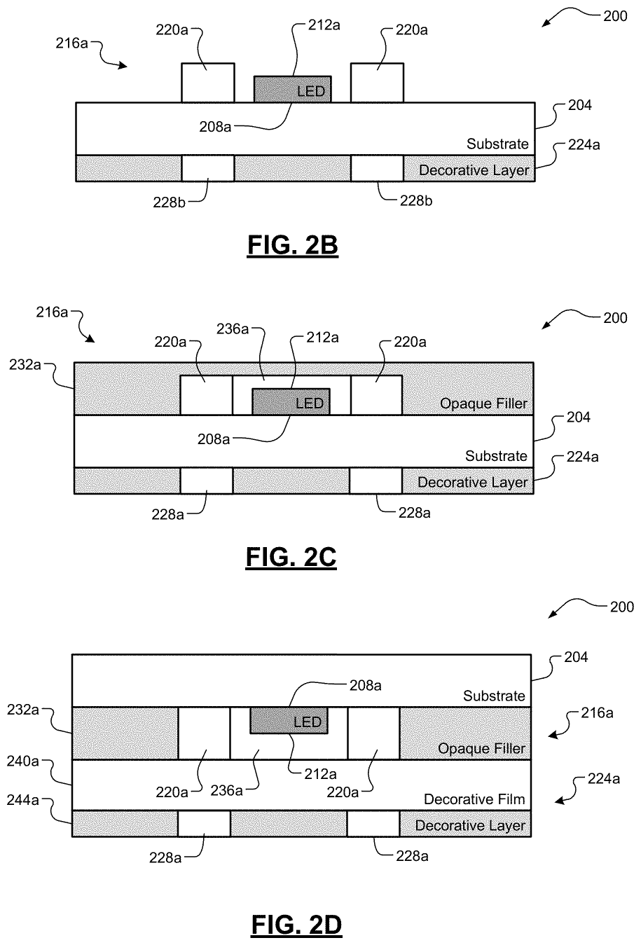

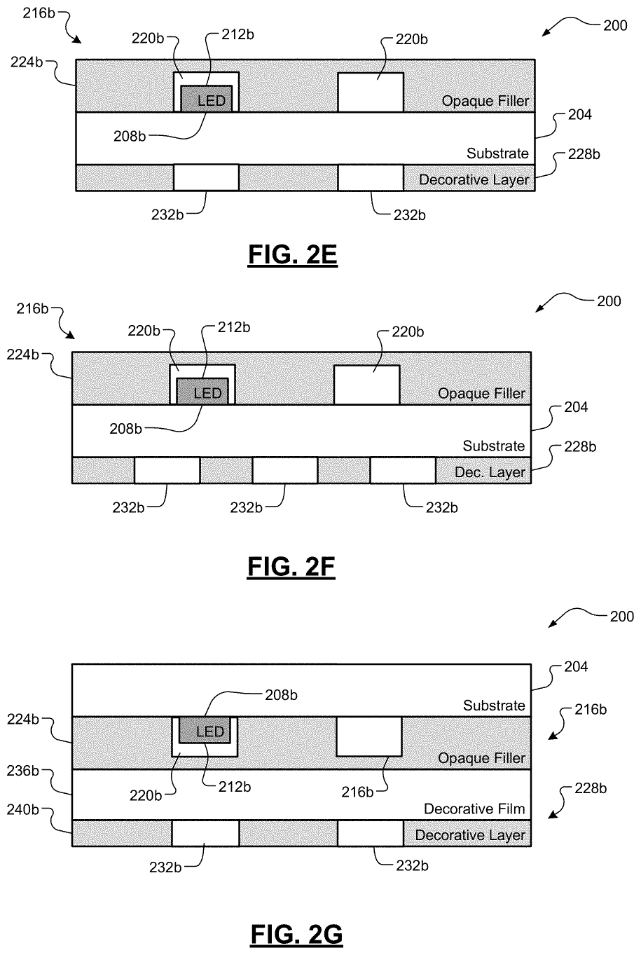

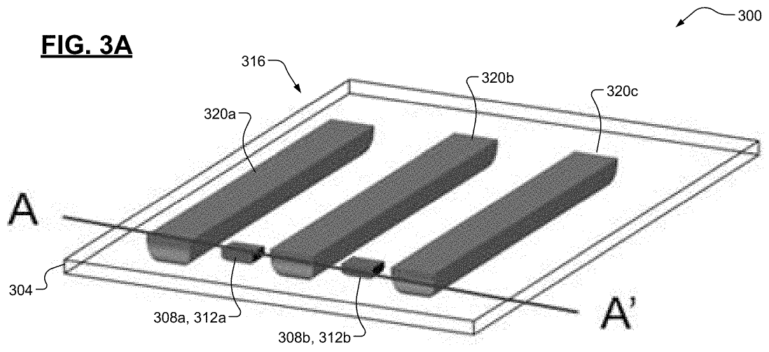

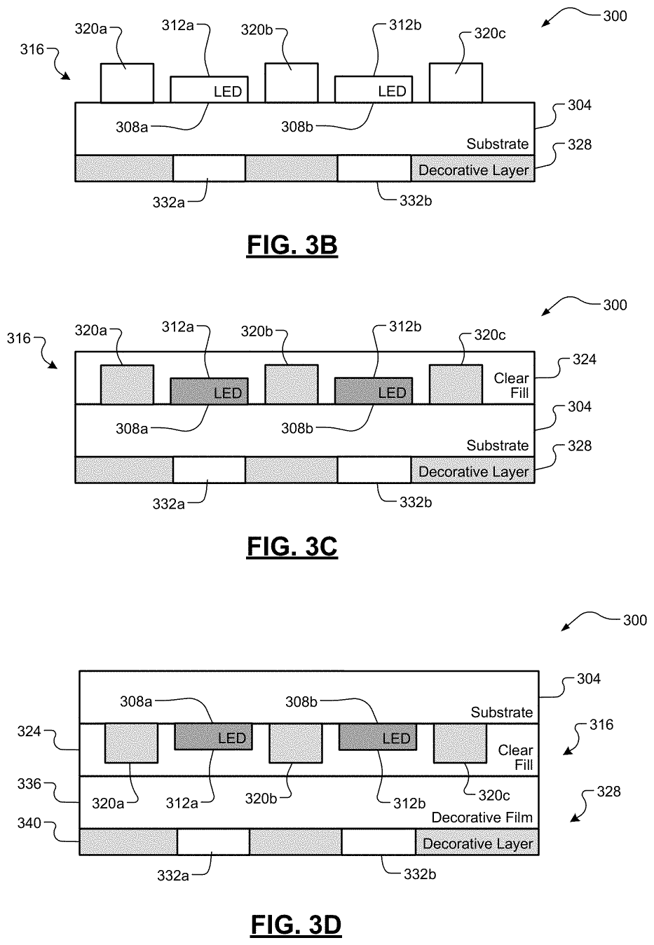

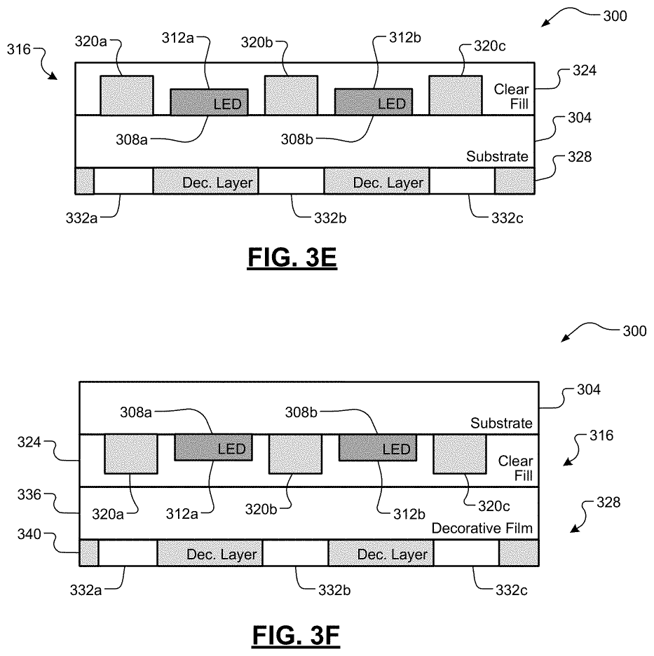

Referring now to FIGS. 1A-1D, a first set of embodiments of an in-mold electronic (IME) device 100 are illustrated. FIG. 1A illustrates a side view of the IME device 100 and FIGS. 1B-1D illustrate various cross-sectional views (A-A′) of the IME device 100. The IME device 100 generally comprises a substrate 104 having a conductive track or trace 108 disposed thereon as well as an electronic device 112 disposed thereon and electrically connected to the conductive track 108. The conductive track 108 (and possible the electronic device 112) could be applied via any suitable process, such as electronic circuit printing. The electronic device 112 could also be affixed to the substrate 104 using a conductive adhesive. The same goes for the other configurations illustrated in FIGS. 2A-2G and 3A-3F and as described below. While the electronic device 112 is described herein as a light-emitting diode (LED), it will be appreciated that the IME device 100 could include any other suitable electronics. Non-limiting examples of the material for the substrate 104 include plastic or polymer materials, such as polycarbonates (PC), polymethyl methacrylates (PMMA), acrylonitrile butadiene styrenes (ABS), styrene acrylics, styrene acrylonitrile polymers, polyamides, and combinations thereof. Depending on the configuration of the IME device 100, the substrate 104 could be opaque or translucent or transparent.

Referring now to FIGS. 1B-1D, various configurations of the IME device 100 are illustrated. In each of FIGS. 1B-1D, a light channel layer 116 is deposited on a first surface of the substrate 104. This deposition could be via a potting process (e.g., a continuous potting process) or another suitable deposition process. The light channel layer 116 defines a transparent or translucent portion 120 surrounding the LED 112. In FIGS. 1B-1C, the substrate 104 is transparent or translucent and a decorative layer 124 is applied to an opposing second surface of the substrate 104. The decorative layer 124 defines a transparent or translucent portion 128 through which light emitted by the LED 112 may flow. This flow of emitted light could be to an exterior of the device 100 or to an interior portion of the device 100 (i.e., below one or more outermost layers). A remainder of the decorative layer 124 could be opaque such that light does not flow therethrough. In FIG. 1C, the light channel layer 116 further comprises an opaque portion 132 (e.g., an opaque filler material) that is deposited about or around and above (i.e., surrounding) the transparent or translucent portion 120. In FIG. 1D, the decorative layer 124 is applied to the light channel layer 116 and further comprises a transparent or translucent decorative film 136 and an outer decorative layer 140 defining the transparent or translucent portion 128. In this configuration, the substrate 104 could be opaque so as to direct light emitted by the LED 112. It will be appreciated that in some configurations, the opaque portion 132 of the light channel layer 116 could have different colored inks disposed thereon or other suitable additives or materials incorporated therewith to filter the light spectrum of the LED 112. While the LED 112 is shown as being aligned with the transparent or translucent portion 128 of the decorative layer 124 in each of FIGS. 1B-1D to provide a direct illumination effect, it will be appreciated that these could not be aligned so as to provide an indirect illumination effect, e.g., preventing hotspots and allowing for a more even illumination of longer and/or wider surfaces.

Referring now to FIGS. 2A-2G, a second set of embodiments of an IME device 200 are illustrated. FIG. 2A illustrates a side view of the IME device 200 and FIGS. 2B-2D illustrate various cross-sectional views (A-A′) of the IME device 200. The IME device 200 generally comprises a substrate 204 having conductive tracks or trace 208a, 208b, 208c disposed thereon as well as electronic devices 212a, 212b, 212c disposed thereon and electrically connected to the respective conductive tracks 208a, 208b, 208c. While the electronic devices 212a, 212b, 212c are described herein as an LED, it will be appreciated that the IME device 200 could include any other suitable electronics. Non-limiting examples of the material for the substrate 204 include plastic or polymer materials, such as PC, PMMA, ABS, styrene acrylics, styrene acrylonitrile polymers, polyamides, and combinations thereof. Depending on the configuration of the IME device 200, the substrate 204 could be opaque or translucent or transparent.

Referring now to FIGS. 2B-2D, various configurations of the IME device 200 are illustrated. In each of FIGS. 2B-2D, a light channel layer 216a is deposited on a first surface of the substrate 204. This deposition could be via a potting process (e.g., a continuous potting process) or another suitable deposition process. The light channel layer 216a defines a transparent or translucent portion 220a proximate to and about the LED 212a. In FIGS. 2B-2C, the substrate 204 is transparent or translucent and a decorative layer 224a is applied to an opposing second surface of the substrate 204. The decorative layer 224a defines a transparent or translucent portion 228a through which light emitted by the LED 212a flows. A remainder of the decorative layer 224a could be opaque such that light does not flow therethrough. In FIG. 2C, the light channel layer 216a further comprises an opaque portion 232a (e.g., an opaque filler material) that is deposited about or around and above (i.e., surrounding) the transparent or translucent portion 220a. It will be appreciated that a portion 236a of the light channel layer 216a could be an air gap, the same transparent or translucent material as transparent or translucent portion 220a, or a different transparent or translucent material as transparent or translucent portion 220a.

For example only, portion 236a of the light channel layer 216a could be transparent for light transmittivity properties and portion 220a of the light channel layer 216a could be translucent for a higher dispersion of light, or vice-versa. Different configurations can bring different and more convenient results depending on the needs of the end product. In FIG. 2D, the decorative layer 224a is applied to the light channel layer 216a and further comprises a transparent or translucent decorative film 240a and an outer decorative layer 244a defining the transparent or translucent portion 228a. In this configuration, the substrate 204 could be opaque so as to direct light emitted by the LED 212a. While the transparent or translucent portion 220a of the light channel layer 216a is shown as being aligned with the transparent or translucent portion 228a of the decorative layer 224a in each of FIGS. 2B-2D to provide a direct illumination effect, it will be appreciated that these could not be aligned so as to provide an indirect illumination effect.

Referring now to FIGS. 2E-2G, more cross-sectional views (B-B′ or C-C′) of the IME device 200 are illustrated. In each of FIGS. 2E-2G, a light channel layer 216b is deposited on the first surface of the substrate 204. This deposition could be via a potting process (e.g., a continuous potting process) or another suitable deposition process. The light channel layer 216b defines a transparent or translucent portion 220b surrounding the LED 212b and an opaque portion 224b (e.g., an opaque filler) thereabout. While FIGS. 2E-2G illustrate cross-section B-B′ in FIG. 2A, it will be appreciated that the left half of FIGS. 2E-2G is also representative of cross-section C-C′ of FIG. 2A and the respective conductive track 208c, electronic device 212c, and light channel layer 216c. In FIGS. 2E-2F, the substrate 204 is transparent or translucent and a decorative layer 224b is applied to an opposing second surface of the substrate 204. The decorative layer 228b defines a transparent or translucent portion 232b through which light emitted by the LED 212b flows. A remainder of the decorative layer 228b could be opaque such that light does not flow therethrough. In FIG. 2G, the decorative layer 228b is applied to the light channel layer 216b and further comprises a transparent or translucent decorative film 236b and an outer decorative layer 240b defining the transparent or translucent portion 232b. In this configuration, the substrate 204 could be opaque so as to direct light emitted by the LED 212b. While the transparent or translucent portion 220b of the light channel layer 216b is shown as being aligned with the transparent or translucent portion 232b of the decorative layer 228b in each of FIGS. 2E and 2G to provide a direct illumination effect, it will be appreciated that these could not be aligned so as shown in FIG. 2F to provide an indirect illumination effect.

Referring now to FIGS. 2A-2G, a second set of embodiments of an IME device 200 are illustrated. FIG. 2A illustrates a side view of the IME device 200 and FIGS. 2B-2D illustrate various cross-sectional views (A-A′) of the IME device 200. The IME device 200 generally comprises a substrate 204 having conductive tracks or trace 208a, 208b, 208c disposed thereon as well as electronic devices 212a, 212b, 212c disposed thereon and electrically connected to the respective conductive tracks 208a, 208b, 208c. While the electronic devices 212a, 212b, 212c are described herein as LEDs, it will be appreciated that the IME device 200 could include any other suitable electronics. Non-limiting examples of the material for the substrate 204 include plastic or polymer materials, such as PC, PMMA, ABS, styrene acrylics, styrene acrylonitrile polymers, polyamides, and combinations thereof. Depending on the configuration of the IME device 200, the substrate 204 could be opaque or translucent or transparent.

Referring now to FIGS. 2B-2D, various configurations of the IME device 200 are illustrated. In each of FIGS. 2B-2D, a light channel layer 216a is deposited on a first surface of the substrate 204. This deposition could be via a potting process (e.g., a continuous potting process) or another suitable deposition process. The light channel layer 216a defines a transparent or translucent portion 220a proximate to and about the LED 212a. In FIGS. 2B-2C, the substrate 204 is transparent or translucent and a decorative layer 224a is applied to an opposing second surface of the substrate 204. The decorative layer 224a defines a transparent or translucent portion 228a through which light emitted by the LED 212a flows. A remainder of the decorative layer 224a could be opaque such that light does not flow therethrough. In FIG. 2C, the light channel layer 216a further comprises an opaque portion 232a (e.g., an opaque filler material) that is deposited about or around and above (i.e., surrounding) the transparent or translucent portion 220a. It will be appreciated that a portion 236a of the light channel layer 216a could be an air gap or the same transparent or translucent material as transparent or translucent portion 220a. In FIG. 2D, the decorative layer 224a is applied to the light channel layer 216a and further comprises a transparent or translucent decorative film 236a and an outer decorative layer 240a defining the transparent or translucent portion 228a. In this configuration, the substrate 204 could be opaque so as to direct light emitted by the LED 212a. While the transparent or translucent portion 220a of the light channel layer 116a is shown as being aligned with the transparent or translucent portion 228a of the decorative layer 224a in each of FIGS. 2B-2D to provide a direct illumination effect, it will be appreciated that these could not be aligned so as to provide an indirect illumination effect.

Referring now to FIGS. 3A-3F, a third set of embodiments of an IME device 300 are illustrated. FIG. 3A illustrates a side view of the IME device 300 and FIGS. 3B-3D illustrate various cross-sectional views (A-A′) of the IME device 300. The IME device 300 generally comprises a substrate 304 having conductive tracks or trace 308a, 308b disposed thereon as well as electronic devices 312a, 312b disposed thereon and electrically connected to the respective conductive tracks 308a, 308b. While the electronic devices 312a, 312b are described herein as LEDs, it will be appreciated that the IME device 300 could include any other suitable electronics. Non-limiting examples of the material for the substrate 304 include plastic or polymer materials, such as PC, PMMA, ABS, styrene acrylics, styrene acrylonitrile polymers, polyamides, and combinations thereof. Depending on the configuration of the IME device 300, the substrate 304 could be opaque or translucent or transparent.

Referring now to FIGS. 3B-3D, various configurations of the IME device 300 are illustrated. In each of FIGS. 3B-3D, a light channel layer 316 is deposited on a first surface of the substrate 304. This deposition could be via a potting process (e.g., a continuous potting process) or another suitable deposition process. The light channel layer 316 defines first, second, and third portions 320a, 320b, 320c that could either be transparent or translucent (see FIG. 3B) or opaque (see FIGS. 3C-3D). In FIG. 3B, the light channel layer 316 only comprises transparent or translucent portions 320a, 320b, 320c. In FIGS. 3C-3D, on the other hand, the light channel layer 316 comprises opaque portions 320a, 320b, 320c and a transparent or translucent portion 324 (e.g., a clear filler) disposed thereabout. In FIGS. 3B-3C, the substrate 304 is transparent or translucent and a decorative layer 328 is applied to an opposing second surface of the substrate 204. The decorative layer 328 defines a transparent or translucent portions 332a, 332b through which light emitted by the LEDs 312a, 312b flows. A remainder of the decorative layer 328 could be opaque such that light does not flow therethrough. In FIG. 3D, the decorative layer 328 is applied to the light channel layer 316 and further comprises a transparent or translucent decorative film 336 and an outer decorative layer 340 defining the transparent or translucent portions 332a, 332b. In this configuration, the substrate 304 could be opaque so as to direct light emitted by the LED 312a.

While the LEDs 312a, 312b are shown as being aligned with the transparent or translucent portions 332a, 332b of the decorative layer 328 in each of FIGS. 3B-3D to provide a direct illumination effect, it will be appreciated that these could not be aligned so as to provide an indirect illumination effect. FIGS. 3E-3F, for example, illustrate such alternative embodiments of FIGS. 3C-3D. More specifically, in FIGS. 3E-3F, transparent or translucent portions 328a, 328b, and 328b are not aligned with the LEDs 312a, 312b and instead the opaque portions of the decorative layer are aligned with the LEDs 312a, 312b. These embodiments provide an indirect illumination effect while also keeping a maximum level of illumination insulation. Additionally, non-complete insulators could be utilized to facilitate this effect with separated and independent illumination areas.

It will be appreciated that the FIGS. described above are not drawn to scale and are merely for illustrative purposes only. For example only, the sizing the gap between the blocking elements 320a-320c and the edge of the clear fill 324 could determine how well isolated each illuminated portion is. Similarly, it will be appreciated that some of the layers/features illustrate could have different shapes, such as rounded portions covering the LEDs.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known procedures, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The term “and/or” includes any and all combinations of one or more of the associated listed items. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

It should be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. An in-mold electronic (IME) device, comprising:
a substrate;
a conductive track disposed on or proximate to a first surface of the substrate;
a light-emitting diode (LED) disposed on the first surface of the substrate, electrically connected to the conductive track, and configured to emit light;
a light channel layer applied to the substrate, the light channel layer comprising a transparent or translucent portion covering or surrounding the LED; and
a decorative layer applied to the light channel layer or an opposing second surface of the substrate, the decorative layer defining an opaque portion and a transparent or translucent portion through which light emitted by the LED flows.

2. The IME device of claim 1, wherein the substrate is transparent or translucent and the decorative layer is disposed on the opposing second surface of the substrate.

3. The IME device of claim 2, wherein the light channel layer further comprises an opaque portion surrounding its transparent or translucent portion.

4. The IME device of claim 1, wherein the light channel layer further comprises an opaque portion surrounding the transparent or translucent portion.

5. The IME device of claim 4, wherein the decorative layer is disposed on the opaque portion of the light channel layer.

6. The IME device of claim 5, wherein the decorative layer comprises a transparent or translucent decorative film disposed on the opaque portion of the light channel layer and an outer decorative layer disposed on the decorative film, the outer decorative layer defining an opaque portion and the transparent or translucent portion.

7. An in-mold electronic (IME) device, comprising:
a substrate;
a conductive track disposed on or proximate to a first surface of the substrate;
a light-emitting diode (LED) disposed on the first surface of the substrate, electrically connected to the conductive track, and configured to emit light;
a light channel layer applied to the substrate, the light channel layer comprising a transparent or translucent portion proximate to and about the LED; and
a decorative layer applied to the light channel layer or an opposing second surface of the substrate, the decorative layer defining an opaque portion and a transparent or translucent portion through which light emitted by the LED flows.

8. The IME device of claim 7, wherein the transparent or translucent portion of the light channel layer does not contact the LED, wherein the substrate is transparent or translucent, wherein the decorative layer is disposed on the opposing second surface of the substrate, and wherein the transparent or translucent portion of the decorative layer is aligned with the light channel layer.

9. The IME device of claim 7, wherein the transparent or translucent portion of the light channel layer surrounds or covers the LED, wherein the substrate is transparent or translucent, wherein the decorative layer is disposed on the opposing second surface of the substrate, and wherein the light channel layer further comprises an opaque portion surrounding its transparent or translucent portion.

10. The IME device of claim 9, wherein the transparent or translucent portion of the decorative layer is aligned with the light channel layer to provide a direct illumination effect.

11. The IME device of claim 9, wherein the transparent or translucent portion of the decorative layer is not aligned with the light channel layer to provide an indirect illumination effect.

12. The IME device of claim 7, wherein the transparent or translucent portion of the light channel layer surrounds or covers the LED, wherein the light channel layer further comprises an opaque portion thereabout its transparent or translucent portion, and wherein the decorative layer is disposed on the light channel layer.

13. The IME device of claim 12, wherein the decorative layer comprises a transparent or translucent decorative film disposed on the light channel layer and an outer decorative layer disposed on the decorative film, the outer decorative layer defining an opaque portion and the transparent or translucent portion.

14. The IME device of claim 13, wherein the transparent or translucent portion of the outer decorative layer is aligned with the transparent or translucent portion of the light channel layer to provide a direct illumination effect.

15. The IME device of claim 13, wherein the transparent or translucent portion of the outer decorative layer is not aligned with the light channel layer to provide an indirect illumination effect.

16. An in-mold electronic (IME) device, comprising:
a substrate;
a conductive track disposed on or proximate to a first surface of the substrate;
a light-emitting diode (LED) disposed on the first surface of the substrate, electrically connected to the conductive track, and configured to emit light;
a light channel layer applied to the substrate, the light channel layer comprising a transparent or translucent portion or an opaque portion proximate to and not in contact with the LED; and
a decorative layer applied to the light channel layer or an opposing second surface of the substrate, the decorative layer defining an opaque portion and a transparent or translucent portion through which light emitted by the LED flows.

17. The IME device of claim 16, wherein the light channel layer comprises the transparent or translucent portion proximate to and not in contact with the LED, wherein the substrate is transparent or translucent, wherein the decorative layer is disposed on the opposing second surface of the substrate, and wherein the LED is aligned with the transparent or translucent portion of the decorative layer.

18. The IME device of claim 16, wherein the light channel layer comprises the opaque portion proximate to and not in contact with the LED and a transparent or translucent portion surrounding its opaque portion and the LED, wherein the substrate is transparent or translucent, wherein the decorative layer is disposed on the opposing second surface of the substrate, and wherein the LED is aligned with the transparent or translucent portion of the decorative layer.

19. The IME device of claim 16, wherein the light channel layer comprises the opaque portion proximate to and not in contact with the LED and a transparent or translucent portion surrounding its opaque portion and the LED, wherein the substrate is transparent or translucent, wherein the decorative layer is disposed on the light channel layer, and wherein the LED is aligned with the transparent or translucent portion of the decorative layer.

20. The IME device of claim 19, wherein the decorative layer comprises a transparent or translucent decorative film disposed on the light channel layer and an outer decorative layer disposed on the decorative film, the outer decorative layer defining an opaque portion and the transparent or translucent portion.
